(19) United States
(12) Patent Application Publication
(10) Pub. No.: US 2012/0275087 A1
(43) Pub. Date: Nov. 1, 2012

(54) SYSTEMS AND METHODS FOR STORING AND OPERATING MULTIPLE DISPLAYS IN A PORTABLE CASE

(76) Inventors: Robert William Corey, Glenn Allen, VA (US); Paul Joseph Indelicato, Locust Grove, VA (US); Andrew Wade Jernigan, Richmond, VA (US)

(21) Appl. No.: 13/094,612

(22) Filed: Apr. 26, 2011

(51) Int. Cl. H05K 5/00; H05K 5/02; B23P 11/00; A47B 95/02

(52) U.S. Cl. 361/679.01; 312/244; 29/428

(57) ABSTRACT

A portable system for display storage and use where at least a first and second display can be stored in the portable system and where the portable system includes supporting structures for arranging multiple displays in a viewing configuration. The portable system includes a housing and first and second displays stored in the housing, where the first display is coupled to a movable supporting member operable to move the displays between a stowed and a viewing position. The displays are adapted with corresponding mounts arranged along a peripheral edge of each display such that the displays may be coupled via the corresponding mounts. Housing mounts sized to engage the corresponding mounts on the second display may be directly or indirectly coupled to the housing and may be used to secure the second display within the housing during transport.

### TECHNICAL FIELD

The technical field of this disclosure relates generally to a portable case for storing and operating multiple displays, and particularly, to a portable case capable of both securely storing the displays and also functioning as a support mount for arranging the displays for viewing.

### BACKGROUND INFORMATION

A portable display unit is useful in an environment or location that simply lacks structures to permanently mount or use a display. A portable display unit may also be useful in a situation where it is unfeasible or undesirable to permanently mount a display, for instance, in occasions where a display is needed only for a short period of time, such as during search and rescue operations or military tactical operations in the field.

### SUMMARY OF THE DISCLOSURE

The present inventors have recognized a need for a portable display unit that houses multiple displays and includes all the necessary mounting structures for assembling and viewing the multiple displays. The present inventors have also identified a need for such a system that can be easily transported, quickly assembled and dissembled on site, and easily repackaged for future transport and use. In addition, the present inventors have identified a need for such a portable display unit that can be arranged in a variety of display configurations as desired without requiring extensive modifications to the portable display unit, the housing, or the displays.

The present inventors have also identified a need for a ruggedized housing for such a system that it is capable of withstanding extreme stress and force to protect the displays. For example, the portable display unit may be dropped from high altitudes, such as being parachuted down to a military site, or subjected to nearby explosions. The present inventors have also recognized a need for such a housing that is impermeable to water, sand, dirt, or other environmental debris that may damage the displays or other mounting structures.

Some embodiments for a portable system for display storage and use may include a housing having a bottom wall and a plurality of side walls defining a cavity. The housing may further include a first display housed within the cavity, where the first display is coupled to a movable supporting member. A second display may be removably coupled to the first display to form a multiple-display unit. The movable supporting member may be operable to move the first and second displays between a stow position where the first display is housed in the cavity and a viewing position where the multiple-display unit is extended to a height above the housing. In other embodiments, the first and second displays may be rotatably coupled to each other such that the displays are freely rotatable in relation to one another to provide for multiple viewing angles as desired.

Other embodiments of a portable system may further include housing mounts directly or indirectly coupled to an interior bottom surface or at least one of an interior side wall surface of the housing, where the housing mounts are adapted to couple with connecting mounts on the second display to secure the second display in the housing. In some embodiments, the housing mounts may be attached or formed as a unitary piece of a rigid support frame that is attached to the interior bottom surface.

Other embodiments for a portable system for display storage and use may include a housing having a bottom wall and a plurality of side walls, where each of the plurality of side walls have an exterior-facing surface. The portable system may further include handles for carrying the portable system and at least one latch coupled to at least one of the exterior-facing surfaces of the plurality of side walls. An enclosure may be included for enclosing contents within the housing, where the enclosure is secured to the housing by the at least one latch. Additionally, at least one balancing foot may be coupled to the housing, the balancing foot being extendable for helping balance the portable system while on a surface.

Some embodiments for a method of operation and use of the portable system for display storage and use may include opening a portable container housing a first and second display, where the first display is coupled to a movable supporting member. The method may further include removing the second display from the portable container and coupling the second display to the first display. Additionally, the method may include elevating the coupled displays using the movable supporting member.

Other embodiments may include coupling a movable supporting member to an interior housing of a portable container and coupling a first display to the movable supporting member. Additionally, the method may include arranging storing mounts on an interior surface of the portable container and coupling a second display with the storing mounts, where the first and second displays are spaced apart in relation to each other.

Additional aspects and advantages will be apparent from the following detailed description of example embodiments, which proceeds with reference to the accompanying drawings.

### BRIEF DESCRIPTION OF THE DRAWINGS

FIG. 1 is an isometric view of a portable case for display storage and use in a closed configuration.

FIG. 2 is a back view of the portable case of FIG. 1.

FIG. 3 is a top plan view of the portable case of FIG. 1 in an open configuration illustrating first and second displays in a stow position.

FIG. 4 is an isometric view of the portable case of FIG. 3 illustrating a plurality of storing mounts for securing the second display.

FIG. 4A is an isometric view of a mounting frame for attaching the storing mounts.

FIG. 5 is an isometric view of the portable case in an open configuration illustrating a multiple-display unit with first and second displays extending vertically outward from the case.

FIG. 6 is a back view of the portable case of FIG. 5 illustrating a coupling of first and second displays.

FIG. 7 is an isometric view illustrating the coupling of first and second displays with the first display in a stow position.

FIG. 8 is a back view of the portable case of FIG. 7 illustrating the coupling of first and second displays via a plurality of mounts and pin clips.

FIG. 8A is an enlarged view of a pin clip illustrating a spherical body and an elongated pin for securing first and second displays.

FIG. 9 is an isometric view of another embodiment of the portable case with first and second displays arranged side-by-side in the same plane with each display coupled to a supporting member.

FIG. 10 is an isometric view illustrating another embodiment of the portable case with a plurality of side-by-side and vertically stacked displays.

FIG. 11 is an isometric view illustrating another embodiment of the portable case having a pair of side-mounted, individually rotatable displays.

FIG. 12 is a back view of the portable case illustrating hinged connectors and supports for the individually rotatable displays.

FIG. 13 is an isometric view illustrating another embodiment of the portable case with an array of vertically-stacked displays each supporting a side-mounted, individually rotatable display.

### DETAILED DESCRIPTION

With reference to the drawings, this section describes particular embodiments and their detailed construction and operation. The embodiments described herein are set forth by way of illustration only and not limitation. The described features, structures, characteristics, and methods of operation may be combined in any suitable manner in one or more embodiments. In view of the disclosure herein, those skilled in the art will recognize that the various embodiments can be practiced without one or more of the specific details or with other methods, components, materials, or the like. In other instances, well-known structures, materials, or methods of operation are not shown or not described in detail to avoid obscuring more pertinent aspects of the embodiments.

In the following description of the figures and any example embodiments, it should be understood that any reference to using the system described herein for military operations or combat settings is merely one use for such a system and should not be considered as limiting. Other uses for a system with the characteristics and features as those described herein may also be possible, such as use in search and rescue operations, disaster management, personal use in a home, business use in an employment setting, or recreational use in outdoor settings.

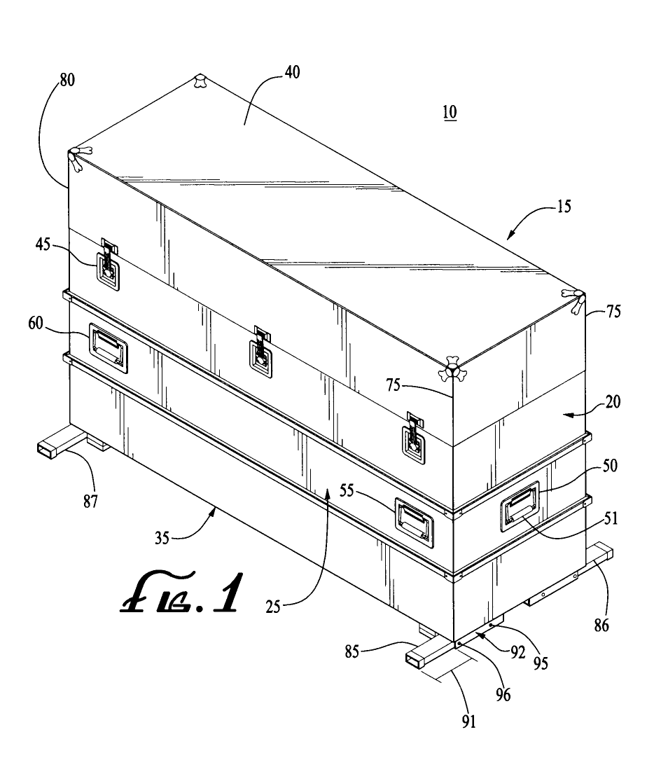

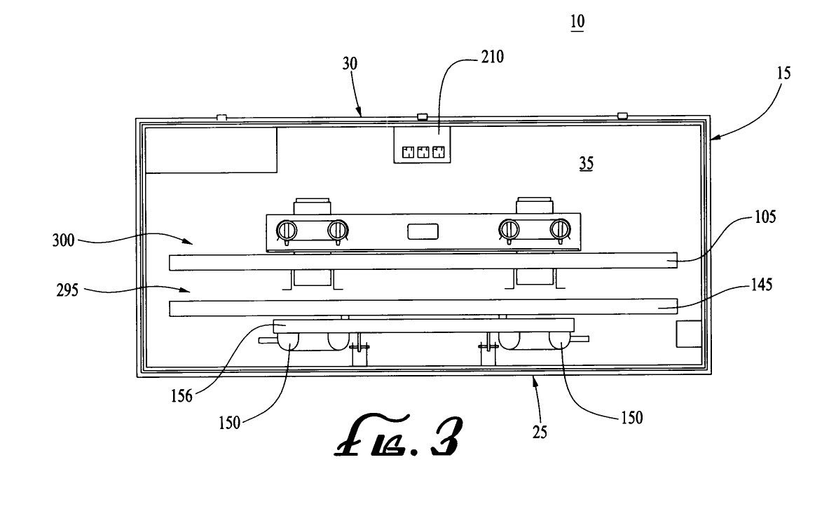

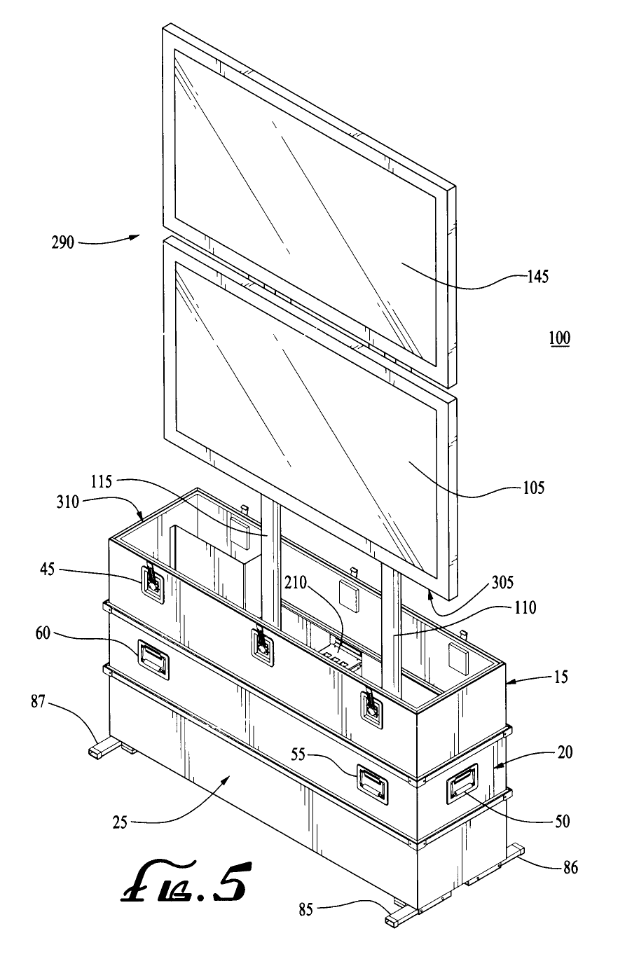

With reference to FIGS. 1-8, in one example operation, a portable display system 10 may be carried to a desired location, such as a military site on a battlefield, by one or more people using one or more of a plurality of handles 50, 55, 60, 65, 70 arranged around a housing 15. Once at the military or other operations management site, a lid 40 may be removed and the portable display system 10 opened to reveal a first display 105 and a second display 145 housed therein. The first display 105 may be coupled to first and second movable supporting members 110, 115. The second display 145 may be removed and coupled to the first display 105 to form a multiple-display unit 100 as illustrated in FIG. 5. Thereafter, the multiple-display unit 100 can be raised to a viewing position 290 at a desired height to display images, maps, strategic plans, communications, or any other data as desired. The first and second displays 105, 145 may display the same information, different information, or operate cooperatively to create an effectively unified larger display. After the management operation has been completed, the second display 145 can be removed and returned to a stow position 295 in the housing 15, and the first display 105 can also be lowered back to a stow position 300 (see FIG. 3). The portable display system 10 can then be sealed using the lid 40 for future use or transport to another location.

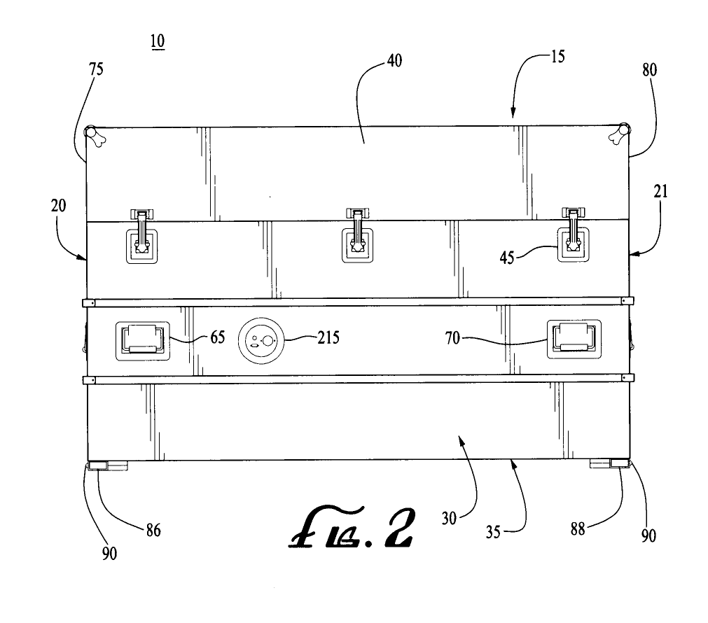

FIGS. 1 and 2 collectively illustrate an example embodiment of a portable display system 10 in a closed configuration. With reference to FIGS. 1 and 2, in some embodiments, the housing 15 encloses and protects the contents of the portable display system 10, including the first and second displays 105, 145. The housing 15 includes a right side wall 20, an opposing left side wall 21 mirroring right side wall 20, opposing front and back side walls 25, 30, and a bottom wall 35. It should be understood that in the descriptions that follow, components described with respect to the right side wall 20 are also preferably included in the opposing left side wall 21 unless stated otherwise. The left side wall 21 may mirror the right side wall 20; however, the components may also be asymmetrically offset.

The right side wall 20 includes at least one handle 50 located along a substantially central region of the right side wall 20. The front and back side walls 25, 30 each include at least two handles 55, 60 and 65, 70, respectively, where the handles 55 and 65 are located in proximity to a right peripheral edge 75 and the handles 60 and 70 are located in proximity to a left peripheral edge 80. The handles 55, 60, 65, and 70 are preferably located at a uniform height, such as in a handle plane, above and parallel to the bottom wall 35.

Preferably, the handle 50 includes a looped grasp 51 abutting a recessed inner region of the handle 50 when at rest, and extending outwardly from the right side wall 20 when the looped grasp 51 is pulled, such as during a carrying operation. The looped grasp 51 is sized and dimensioned to accommodate a person's hand. In an example carrying operation, a person pulls the looped grasp 51 away from the recessed inner region of the handle 50 and clutches the looped grasp 51. Once the carrying operation is complete, the person releases the looped grasp 51, which then swings back into its rest position in the recessed inner region of the handle 50. It should be understood that the previous description of the features and characteristics of the handle 50 may apply to each of the handles 55, 60, 65, 70. However, it should also be understood that the handles 50, 55, 60, 65, 70 may each incorporate individually unique features and characteristics other than those explicitly described herein.

In other embodiments, the position and arrangement of the handles along the housing 15 may support a variety of configurations. For example, the handles can be arranged at varying heights above the bottom wall 35 or spaced out differently in relation to the left and right peripheral edges 75, 80. In another embodiment, the number of handles could be greater or less than the embodiment containing six handles described herein. In still other embodiments. the handles could be made of a rope or other fabric material having opposing edges rigidly attached to the housing 15 to create a loop handle.

As previously discussed, the housing 15 further includes the lid 40 enclosing the portable display system 10. The lid 40 is releasably attached via a plurality of latches 45 positioned along the front and back side walls 25, 30. The latches 45 need not all be of the same type or same dimensions. The latches 45 may be spring-loaded latches or other similar latches or locking means suitable for releasably attaching the lid 40 such that the portable display system 10 is impermeable to water, sand, dirt, or other environmental debris when in a closed configuration to protect the first and second displays 105, 145 and other contents therein. In some embodiments, the number and arrangement of the latches 45 on the housing 15 may vary. For example, the portable display system 10 may include additional latches 45 on the right and left side walls 20, 21 for added support. In still other embodiments, the back side wall 30 may include hinged latches or connectors (not shown) for keeping the lid 40 partly and hingedly attached to the housing 15 when the portable display system 10 is in an open configuration.

With reference again to FIGS. 1 and 2, the housing 15 also preferably includes at least one foot 85 located along a bottom wall 35 for providing additional support and stability to the portable display system 10 when it is resting on a surface. In some embodiments, the foot 85 may be oriented parallel to the right side wall 20. A second foot 86 may be laterally spaced apart from the foot 85 and also oriented parallel to the right side wall 20. The left side wall 21 may also include corresponding feet 87, 88 laterally spaced apart and oriented parallel to the left side wall 21.

The foot 85 includes a depressible push-pin button 90 and at least a pair openings 95, 96 arranged along a side wall 92 of the foot 85, where the side wall 92 is preferably parallel to and in the same plane as the right side wall 20 of the housing 15. In some embodiments, the side wall 92 may be parallel to but in a different plane in relation to the right wall 20 such that the side wall 92 may be tucked underneath the housing 15 or extended outward beyond the right side wall 20. The pair of openings 95, 96 are sized to receive the push-pin button 90 for releasably locking the foot 85 at a desired length 91 for optimizing the stability of the portable display system 10. It should be understood that although not explicitly mentioned, any description of features and characteristics of the foot 85 may correspond to each of the feet 86, 87, 88.

In an example operation, the push-pin button 90 initially engages opening 95 when the foot 85 is in a stow or transport position. To extend and secure the foot 85, the push-pin button 90 is depressed and the foot 85 is extended until the push-pin button 90 engages the opening 96, thereby locking the foot 85 in position. To retract, the push-pin button 90 may be depressed and the foot 85 retracted until the push-pin button 90 reengages opening 95.

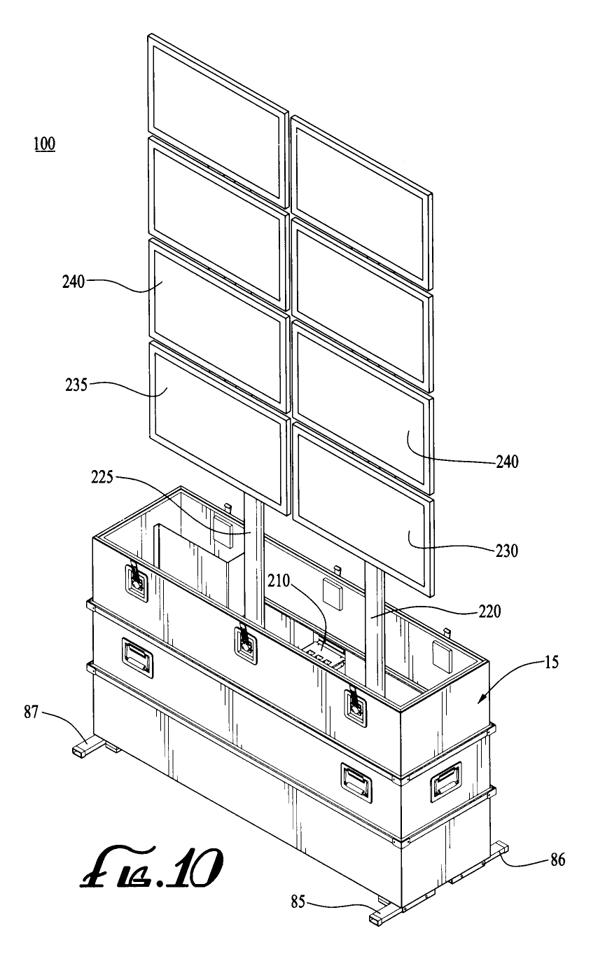

In other embodiments, the foot 85 may include a plurality of openings spaced apart and collinear with openings 95, 96 to provide a number of locking points to lock the foot 85 at a plurality of positions that determine a variety of lengths 91. The length 91 to extend the foot 85 may depend on many factors, such as for example, on the stability of the surface or terrain where the portable display system 10 is resting, on the weight of the particular configuration portable display system 10, or on whether the portable display system 10 is in a closed configuration or an open configuration with multiple displays. For example, in an open configuration with multiple displays (such as shown in FIG. 10), the system may be heavy and the feet 85, 86, 87, 88 may need to be extended to a longer length 91. On the other hand, when the portable display system 10 is in a closed configuration with only two displays (such as shown in FIG. 5), the feet 85, 86, 87, 88 may need only a small length extension or none at all.

In other embodiments, the right side wall 20 may include the feet 85, 86 as described and the opposing left side wall 21 may instead include wheels or casters for simplifying transport and movement of the portable display system 10. In such an embodiment, a person may grab the handle 50 and lift the portable display system 10 onto the wheels or casters and push or pull the portable display system 10 to a desired location. In yet other embodiments, the feet 85, 86, 87, 88 may be entirely replaced with wheels or casters having individual locking mechanisms such that the portable display system 10 can be easily transported to a position and the wheels or casters locked. In still other embodiments, the portable display system 10 may include both the feet 85, 86, 87, 88 and the individually locking four wheels or casters, where the wheels aid in transporting the portable display system 10 and the feet 85, 86, 87, 88 help support the portable display system 10 when in operation.

Preferably, the housing 15 is constructed of metallic components that are capable of withstanding extreme forces and vibrations. In one embodiment, the housing 15 can withstand drop testing and vibratory testing ranging from 5 Hz to 500 Hz for transit qualification. The housing 15 is preferably constructed of lightweight, but durable metals, such as aluminum, so that the portable display system 10 can be transported without substantial effort and have the structural integrity to withstand the extreme forces it may be subject to, such as on a battlefield. In other embodiments, the housing 15 can be constructed of metals heavier or lighter than aluminum, or metal alloys, such as steel.

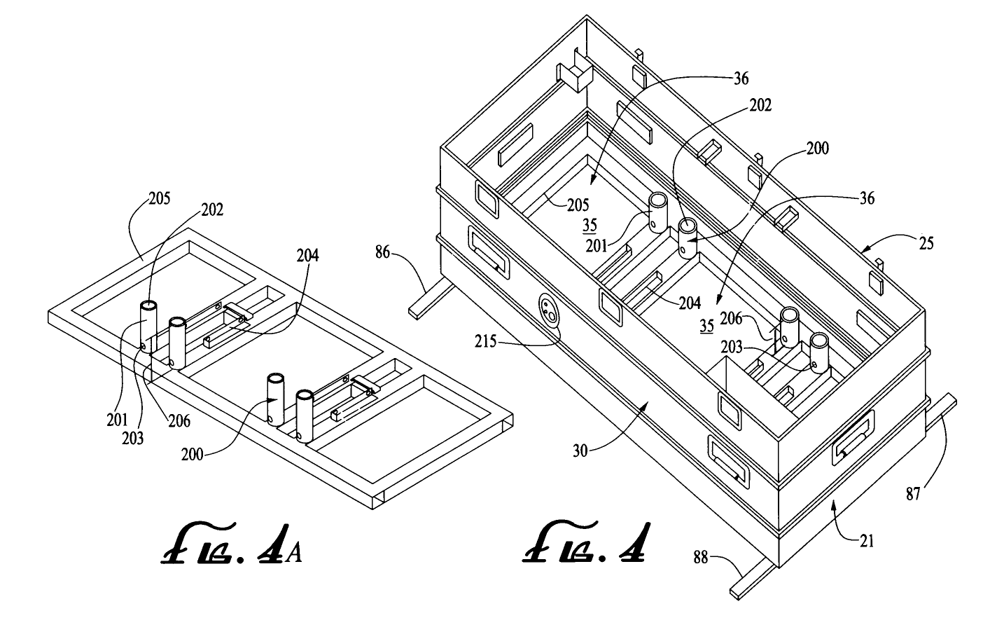

FIG. 3 illustrates the portable display system 10 in an open configuration illustrating the first and second displays 105, 145 in stow positions 295, 300 and FIG. 4 illustrates a plurality of housing mounts 200 in the housing 15 for securing the second display 145. With reference to FIGS. 3 and 4, in some embodiments, the first and second displays 105, 145, are stored and spaced apart from each other in housing 15. The first display 105 may be coupled to first and second movable supporting members 110, 115 (see FIGS. 5-8) such that the first display 105 is secure within the housing 15. The second display 145 may be secured to the housing 15 via a plurality of housing mounts 200 arranged on an interior surface of the bottom wall 35. The second display 145 may be of similar dimension and weight as the first display 105 or it may have different dimensions and weight. The second display 145 is housed in the housing 15 spaced apart from the first display 105 such that the first and second displays 105, 145 are preferably supported in generally parallel planes that are generally parallel in relation to the planes of the front and back side walls 25, 30. However, the planes of the first and second displays 105, 145 need not be parallel in relation to each other nor to the planes of the front and back side walls 25, 30. For example, the planes of the first and second displays 105, 145 may be perpendicular to the plane of the bottom wall 35 but may be at the same or different angle with respect to the planes of the front and back side walls 25, 30. Alternatively, the planes of the first and second displays 105, 145 may be angled with respect to the plane of the bottom wall 35 and be parallel or angled with respect to each other.

FIG. 4 shows the interior of the housing 15 with the first and second displays 105, 145 removed to illustrate the housing mounts 200 used to secure the second display 145 within the housing 15. FIG. 4A illustrates a support frame 205 onto with the housing mounts 200 may be attached according to one embodiment. With reference to FIGS. 4 and 4A, in some embodiments, the housing mounts 200 are formed as a unitary piece of the support frame 205, with the housing mounts 200 spaced apart from each other. Alternatively, the housing mounts 200 may be rigidly attached, such as by welding, bolting, or other mounting mechanism, to the support frame 205. In other embodiments, the housing mounts 200 may be welded, bolted, or otherwise mounted directly to an interior surface 36 of the bottom wall 35 or formed as a unitary piece of the bottom wall 35.

In some embodiments, the housing 15 may include housing mounts 200 laterally spaced apart and arranged collinearly in relation to one another, where all the housing mounts 200 are in a single plane generally parallel to the planes of the front and back side walls 25, 30. Alternatively, the housing mounts 200 may each be arranged along planes offset from each other or may be arranged in pairs or groups of housing mounts 200 along different planes. For example, a first set of housing mounts 200 may be arranged collinearly along a first plane near the back wall 30 and a second set of housing mounts 200 may be a arranged collinearly along a second plane further away from the back wall 30, where the spacing between the first set of housing mounts is smaller than the second set of housing mounts 200 such that they are arranged in a trapezoidal-like configuration.

The connecting mounts 150 on the second display 145 may be similarly arranged to engage the housing mounts 200 in the various configurations described or any other configuration. For example, the connecting mounts 150 may be laterally spaced apart and arranged collinearly in relation to one another along a single plane in a configuration matching the arrangement of the housing mounts 200 such that each connecting mount 150 engages one housing mount 200. Alternatively, the connecting mounts 150 can be offset from the plane of the second display 145 and arranged in a trapezoidal-like configuration to match a similar arrangement of the housing mounts 200.

Preferably, the number and arrangement of housing mounts 200 matches the number and arrangement of the connecting mounts 150 on the second display 145 to provide a secure mounting. However, there may be embodiments with more or less housing mounts 200 as compared to the number of the connecting mounts 150 and the housing mounts 200 may be arranged in a variety of configurations in the housing 15 to provide a variety of storing options, including some angular storage orientations with respect to the front and back side walls 25, 30 as described previously. In addition, there may be some embodiments where not all of the connecting mounts 150 are engaged to a housing mount 200.

For example, the housing 15 may include multiple sets of housing mounts 200 arranged collinearly along multiple planes in proximity to either the front side wall 25 or the back side wall 30 such that the second display 145 may be mounted on any set of housing mounts 200 to secure the second display 145 along various planes in relation to the front and back walls 25, 30. Additionally, each set of housing mounts 200 may include more housing mounts 200 than connecting mounts 150 such that the second display 145 may be mounted offset from a middle position between the right and left side walls 20, 21. For example, the second display may be arranged near the right side wall 21 to provide additional storage space for other contents or displays near the left side wall 21.

With reference again to FIGS. 4 and 4A, the support frame 205 is inserted and is preferably rigidly attached to the interior surface 36 of the bottom wall 35. The housing mounts 200 comprise vertically elongate tubular bodies 201 having a height dimension 206 transverse or perpendicular to the plane of the bottom wall 35. The tubular bodies 201 have a top surface opening 202 transverse or perpendicular to the axis of the height dimension 206 and a side opening 203 transverse or perpendicular to the top surface opening 202. The tubular bodies 201 are sized to mate with and engage corresponding connecting mounts 150 arranged on the second display 145 (see FIGS. 5-8). Preferably, the dimensions of the housing mounts 200 are substantially the same as and correspond not only with the connecting mounts 150 of the second display 145, but also with the receiving mounts 130 arranged on the first display 105 (see FIGS. 5-8) such that the second display 145 can be coupled and secured to both the housing mounts 200 and the receiving mounts 130 on the first display without requiring any modifications to the receiving mounts 130, connecting mounts 150, or housing mounts 200.

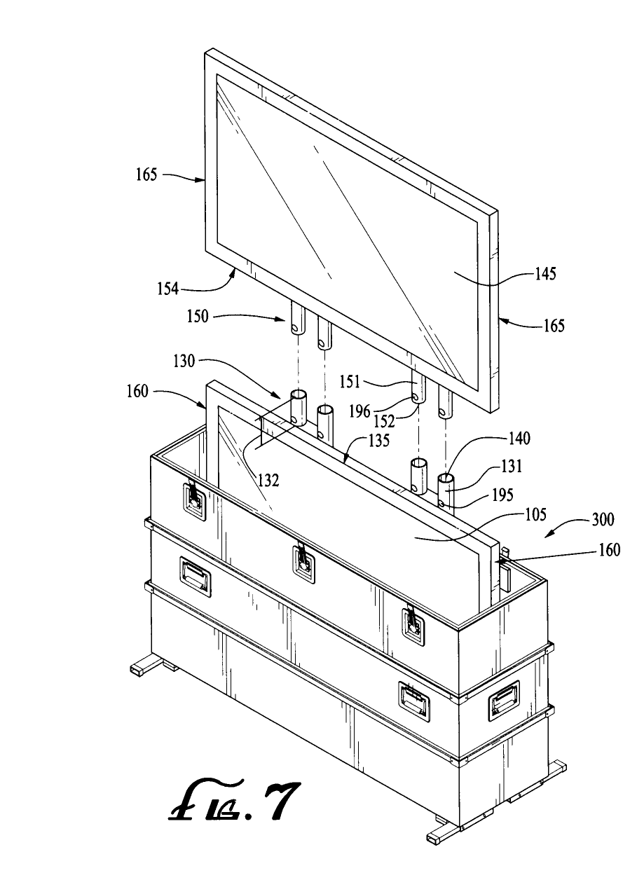

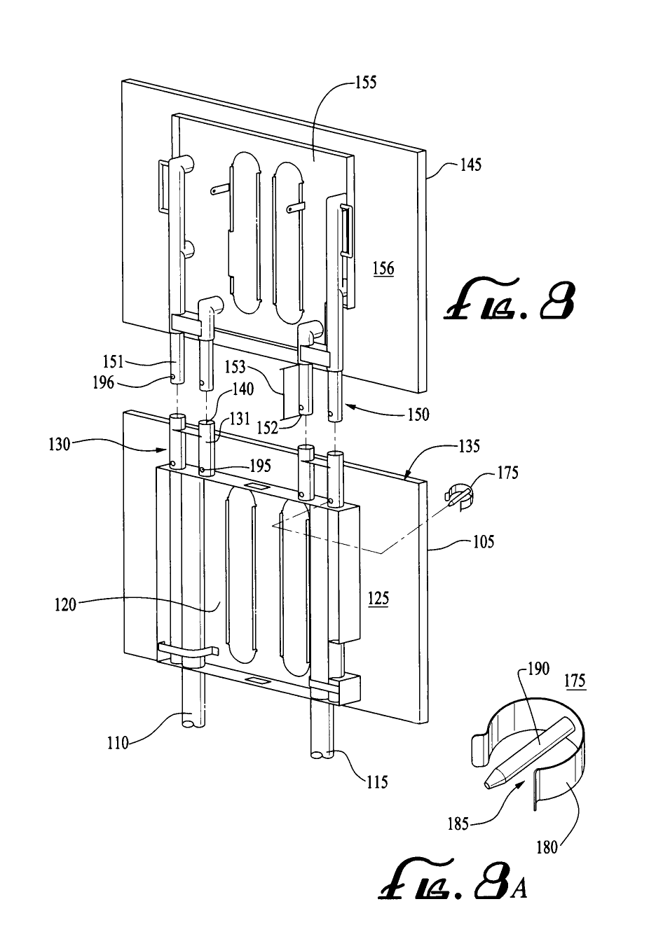

In an example storage operation, the connecting mounts 150 on the second display 145 slide into the top surface opening 202 on the housing mounts 200. A pin clip 175 (see FIG. 8A) may be inserted into the side opening 203 and corresponding side opening 196 of the connecting mount 150 (see FIGS. 7-8) to secure the coupling between the connecting and housing mounts 150, 200. Protective padding or other material may be used throughout to fill in open spaces in the housing 15 to provide additional protection for the first and second displays 105, 145. Some examples of protective padding or packaging may include polystyrene foam and plastic packaging sheets with air pockets.

In some embodiments (see FIGS. 7 and 8), end 152 of the tubular body 151 may have an opening sized such that the connecting mount 150 slides around the tubular body 201 of the housing mount 200 instead of sliding into it. In other embodiments, the tubular bodies 151, 201, and the connecting and housing mounts 150, 200 may be sized such that some of the tubular bodies 151 slide into the corresponding tubular bodies 201 and other tubular bodies 151 slide over and around the corresponding tubular bodies 201. In yet other embodiments, the second display 145 may be bolted, screwed, or otherwise mounted onto an interior surface of the housing 15 to secure the second display 145 during transport.

It should be understood that although the descriptions of the receiving, housing, and connecting mounts 130, 150, 200 are made with reference to a tubular body 131, 151, 201, the mounts 130, 150, 200 may be rectangular, triangular, or any other suitable shape such that the mounts 130, 150, 200 can be slidably engaged with one another. For example, in some embodiments, rails such as “L-” or “I-shaped” rails could be employed as the interior mounts.

FIGS. 5-8A collectively illustrate the portable display system 10 in an open configuration illustrating a multiple-display unit 100 in a raised position comprising a first display 105 coupled with a second display 145. With reference to FIGS. 5-8A, in some embodiments, the first display 105 is coupled to the first and second movable supporting members 110, 115 via a support plate 120 rigidly attached to a back surface 125 of the first display 105. The support plate 120 may be adjoined to the first display 105 using bolts, rivets, or other mounting mechanisms calculated not to compromise or damage the functional integrity of the first display 105.

Similarly, first and second movable supporting members 110, 115 may be coupled to the support plate 120 such as by welding, riveting, bolting, or other methods suitable for secure attachment. In preferred embodiments, first and second movable supporting members 110, 115 are rigidly coupled to the housing 15 via mounts 204 on support frame 205 (see FIG. 4) or coupled directly to the housing 15. The first and second movable supporting members 110, 115 each have a vertical major axis, and the vertical major axes are preferably laterally spaced apart such that they are parallel to each other and aligned within a single plane that is parallel to the front and back side walls 25, 30 so as to provide optimal structural support for the multiple display unit 100.

In some embodiments, the mounts 204 may be rigidly attached to the frame 205 such that the first and second supporting members 110, 115 do not freely rotate with respect to the vertical major axes. However, in some embodiments, the mounts 204 may not be rigidly attached to the frame 205 or housing 15, but may instead secure the first and second supporting members 110, 115 in cooperative rotational engagements such that rotation of mounts 204 with respect to the frame 205 or bottom wall 35 causes rotation of the first and second movable supporting members 110, 115 and rotation of the first and second displays 105, 145. Alternatively, the first and second movable supporting members 110, 115 may be coupled to provide cooperative rotational engagements with respect to the mounts 204, which may be rigidly attached to the frame 205 or housing 15. An advantage of rotational engagement is that the portable display system 10 may be positioned on any sloped or uneven terrain, and the plane of the first and second displays 105, 145 can be independently adjusted as desired without having to lift and reposition the entire housing 15.

Preferably, the first and second movable supporting members 110, 115 have cooperative movement such that the first and second movable supporting members 110, 115 both move in tandem with respect to each other. The first and second movable supporting members 110, 115 raise and lower the multiple-display unit 100 (such as by movement in a plane transverse or perpendicular to the bottom wall 35) between a stow position 300, where the first display 105 is housed in a cavity of the housing 15, and a viewing position 290, where the multiple-display unit 100 is extended to a desired height above the housing 15. The desired height is typically any of a number of variable or preset heights in which a bottom edge 305 of the first display 105 is positioned above a top edge 310 of the housing 15.

The first and second movable supporting members 110, 115 may be electronically coupled to a receiver (not shown) and operable by a remote control unit (not shown) configured to send signals to the receiver to control upward or downward synchronized movement of the first and second movable supporting members 110, 115. The remote control may be configured to automatically raise the multiple-unit display 100 to one or more of a number of preset viewing positions 290. Similarly, the receiver and remote control can additionally be used to rotate the first and second movable supporting members 110, 115 to adjust the plane of the first and second displays 105, 145 with respect to the housing 15.

In other embodiments, the first and second movable supporting members 110, 115 may be mechanically coupled to a lever, crank, or other mechanically operated lifting mechanism such that a person can manually raise and lower the multiple-display unit 100 between the stow position 300 and the viewing position 290. Similarly, the same or a different mechanism can be used to mechanically rotate the first and second movable supporting members 110, 115 to adjust the plane of the first and second displays 105, 145.

In some embodiments, the first display 105 may be coupled only to one movable supporting member 110 positioned along a substantially central axis defined by the midpoint between peripheral edges 160 (see FIG. 7) of the first display 105. In other embodiments, configurations using more than the first and second movable supporting members 110, 115 may be possible, such as configurations that utilize additional support to raise and lower a multiple-display unit 100 having a plurality of displays. For example, a third movable supporting member may be positioned between the first and second movable supporting members 110, 115 and coupled to the support plate 120, such that the third movable supporting member is arranged parallel to the front and back side walls 25, 30 of the housing 15. The third movable supporting member may be symmetrically positioned between or at a different distance from the major axes of the first and second movable supporting members 110, 115.

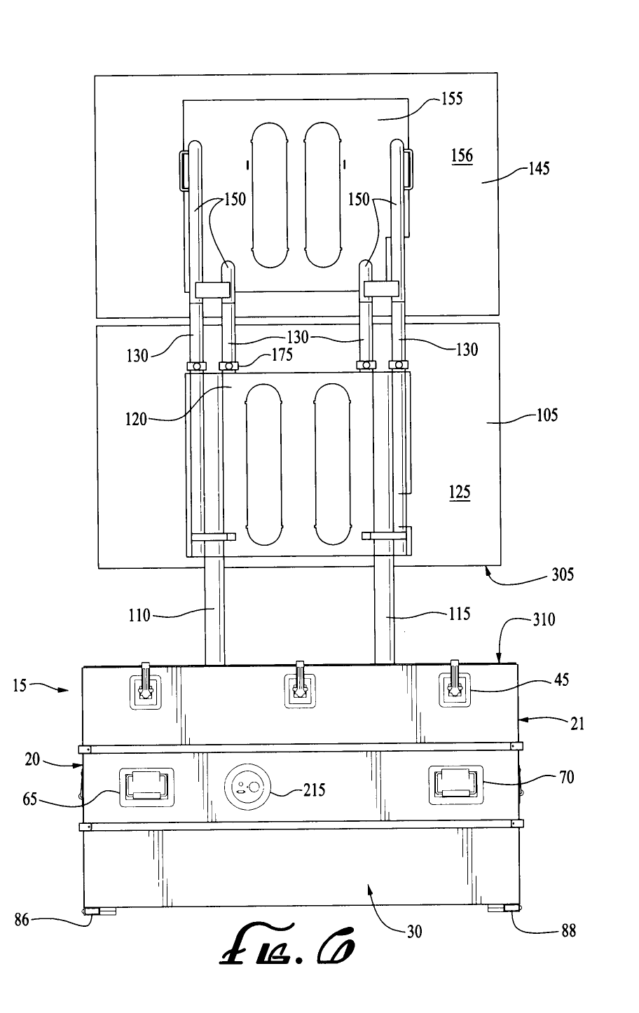

With reference to FIGS. 6-8A, in a preferred embodiment, the first display 105 further includes receiving mounts 130 rigidly attached to the support plate 120 or alternatively formed as a unitary piece of the support plate 120, where the receiving mounts 130 protrude above a top edge 135 of the first display 105 in a plane parallel to or coplanar with the plane of the first display 105. The receiving mounts 130 may comprise vertically elongate tubular bodies 131 having a height dimension 132 transverse or perpendicular to the plane of the bottom wall 35. The tubular bodies 131 have a top surface opening 140 transverse or perpendicular to the axis of the height dimension 132 and a side opening 195 transverse or perpendicular to the top surface opening 140. The tubular bodies 131 are sized to mate with and engage corresponding connecting mounts 150 arranged on the second display 145 (see FIGS. 5-8). As mentioned previously, the dimensions of the receiving mounts 130 are preferably substantially the same as and correspond not only with the connecting mounts 150 of the second display 145, but also with the housing mounts 200 arranged on the bottom wall 35 (see FIGS. 5-8) such that the second display 145 can be coupled and secured to both the housing mounts 200 and the receiving mounts 130 on the first display without requiring any modifications to the receiving mounts 130, connecting mounts 150, or housing mounts 200.

Similarly, the second display 145 includes connecting mounts 150 rigidly attached to a support plate 155 or alternatively formed as a unitary piece of the support plate 155, where the support plate 155 is rigidly attached to a back surface 156 of the second display 145. The connecting mounts 150 preferably protrude below a bottom edge 154 of the second display 145 in a plane parallel to or coplanar with the plane of the second display 145. The connecting mounts 150 may comprise vertically-elongate tubular bodies 151 having a height dimension 153 transverse or perpendicular to the plane of the bottom wall 35. The tubular bodies 151 have a bottom surface opening 152 transverse or perpendicular to the axis of the height dimension 153 and a side opening 196 transverse or perpendicular to the bottom surface opening 152. The tubular bodies 151 are sized to mate with and engage corresponding receiving mounts 130 arranged on the first display 105 (see FIGS. 5-8).

In other embodiments, the receiving and connecting mounts 130, 150 may be rectangular, triangular, or any other suitable shape such that the receiving and connecting mounts 130, 150 can slidably engage one another. It should be understood that although the descriptions herein focus on tubular bodies, the same principles can be adapted for receiving and connecting mounts 130, 150 with rectangular, triangular, or other suitable body shapes.

Preferably, the receiving and connecting mounts 130, 150 are arranged so that each receiving mount 130 corresponds to one connecting mount 150. The receiving and connecting mounts 130, 150 are sized and dimensioned so that the tubular body 151 of the connecting mount 150 slides into the surface opening 140 of the receiving mount 130, such that the tubular body 151 of the connecting mount 150 rests within and is flush against the tubular body 131 of the receiving mount 130. In other embodiments, the bottom surface opening 152 of the connecting mount 150 may instead be sized such that the tubular body 151 of the connecting mount 150 slides around the tubular body 131 of the receiving mount 130. In this embodiment, the tubular body 131 rests within and is flush against the tubular body 151. In other embodiments, the bottom surface opening 152 may instead be a closed end.

In some embodiments, the receiving and connecting mounts 130, 150 may be arranged on the first and second displays 105, 145, respectively, such that peripheral edges 160, 165 of the first and second displays 105, 145, respectively, are vertically aligned in one plane when the first and second displays 105, 145 are coupled in a vertical configuration. In this vertically stacked orientation, the second display 145 is directly above the first display 105 and the first and second displays 105, 145 may each show the same image, different images, or may operate in cooperation as one larger display.

In other embodiments, the first display 105 may include a plurality of receiving mounts 130 to permit not only a vertically stacked and aligned configuration as previously described, but also an offset position where the first and second displays 105, 145 are vertically stacked in the same plane, but the peripheral edges 160, 165 are offset from each other and not vertically aligned. In such a configuration, the connecting mounts 150 on the second display 145 may engage only a select set of receiving mounts 130 depending on the chosen configuration of the first and second displays 105, 145. Alternatively the first display 105 may only include one set of receiving mounts 130 equal in number to the connecting mounts 150, where the receiving mounts 130 are arranged such that the second display 145 is offset from the first display 105.

In another embodiment, the first display 105 may include receiving mounts 130 arranged in an angular orientation in relation to the plane of the first display 105 such that the second display 145 may be mounted in a non-planar configuration in relation to the first display 105. For example, the second display 145 may be mounted such that it tilts forward toward to the front side wall 25 or backward toward to back side wall 30.

With reference to FIGS. 8 and 8A, as the receiving and connecting mounts 130, 150 are slidably engaged, the side openings 195, 196 will be substantially aligned with one another. In some cases, a small rotational correction may be needed to ensure that the side openings 195, 196 are aligned. To stabilize the coupling of the first and second displays 105, 145, a plurality of pin clips 175 (see FIG. 8A) may be inserted through the transverse openings 195, 196. The pin clip 175 comprises a spherical body 180 coinciding with the dimensions of the tubular bodies 131, 151 of the receiving and connecting mounts 130, 150, respectively. The pin clip 175 further includes an open end 185 and an elongated pin 190 extending through the open end 185. The elongated pin 190 has a radius corresponding to the side openings 195, 196 such that the pin clip 175 may be inserted into the side openings 195, 196 to secure the coupling between the receiving and connecting mounts 130, 150. When inserted, the spherical body 180 wraps around and is flush against the tubular body 131 of the receiving mount 130 or against the tubular body 151 of the connecting mount 150 depending on which of the mounts is on the exterior. The same or similar pin clips 175 that were used to secure the second display 145 to the housing mounts 200 may be used to secure the first and second displays 105, 145.

In some embodiments, the tubular bodies 131, 151 of the receiving and connecting mounts 130, 150, respectively, may each include a plurality of openings (not shown) vertically spaced apart and collinear with openings 195, 196, respectively, to provide various insertion points for the pin clip 175. With these plurality of openings, the second display 145 may be vertically stacked at a variety of distances above the first display 105 as desired.

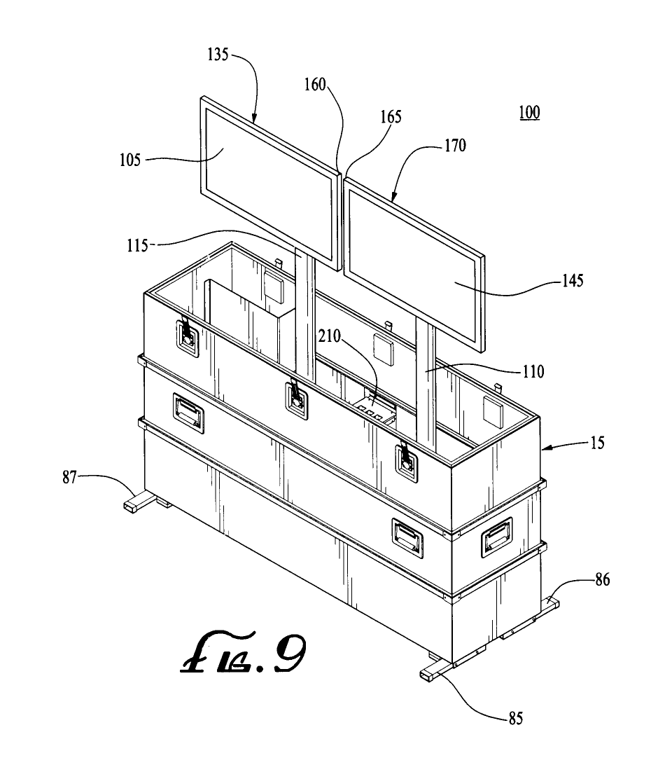

FIG. 9 illustrates another embodiment of the multiple-display unit 100 with the first and second display 105, 145 arranged in a horizontal array. The first display 105 may be coupled to the first movable supporting member 110 and the second display 145 may be coupled to the second movable supporting member 115, where the first and second movable supporting members 110, 115 may be synchronized to raise and lower the first and second displays 105, 145 simultaneously. In other embodiments, the first and second movable supporting members 110, 115 may be independently movable such that the first display 105 can be raised or lowered without moving the second display 145 and vice versa.

In some embodiments, the first and second displays 105, 145 may be coupled using the receiving and connecting mounts 130, 150 to add stability to the multiple-display unit 100. The receiving mounts 130 may be positioned along a peripheral edge 160 of the first display 105 in a transverse or perpendicular (horizontal) orientation in relation to the first and second movable supporting members 110, 115. Similarly, corresponding connecting mounts 150 of the second display 145 are also arranged in a transverse or perpendicular (horizontal) orientation along a peripheral edge 165 of the second display 145. The receiving and connecting mounts 130, 150 may be coupled as previously described and secured with the pin clip 175 so that the first and second displays 105, 145 are laterally spaced apart along a single plane in a side-by-side configuration such that top edges 135, 170 of the first and second display 105, 145 are horizontally aligned.

Alternatively, in the side-by-side configuration, the first display 105 may support the weight of the second display 145 using only the connecting and receiving mounts 130, 150 and the pin clip 175. In this embodiment, the first and second movable supporting members 110,115 may both be coupled to the first display 105, or the portable display system 10 may include only one movable supporting member 110 coupled to the first display 105. In this configuration, it may be desirable to employ tubular bodies 131, 151 having a greater length to better support the second display 145. For example, lengthening one or both sets of the tubular bodies 131, 151 provides a longer length of contact between the tubular bodies 131, 151 so that the weight of the second display 145 can be better distributed along the longer tubular bodies 131, 151. In some embodiments, the length of one or both sets of tubular bodies 131, 151 may be extended to cover more than half the height dimension of the first and second displays 105, 145, respectively. In another embodiment, the tubular bodies 131, 151 may have an intermediate or shorter length, but an additional support plate may be installed to reinforce the horizontal coupling between the first and second display 105, 145.

Although the embodiments generally describe a basic dual monitor configuration with displays of similar weight and dimensions, it should be understood that the multiple-display unit 100 may accommodate any number of displays, including displays with varying weight and dimension, and in multiple configurations, such as a vertically stacked orientation where left and right side peripheral edges of the multiple displays are in the same plane or a horizontal array where top and bottom edges of the multiple displays are in the same plane without departing from the principles of the embodiments described herein. In other embodiments, the displays may be vertically or horizontally offset such that peripheral edges or top and bottom edges are not in the same plane. For instance, the receiving and connecting mounts 130, 150 may be arranged to create a triangular display configuration having two displays coupled and horizontally aligned where a respective top edge of each display is parallel and in the same plane, and a third monitor straddling the two displays with a left portion of the third monitor coupled to the first monitor and a right portion of the third monitor coupled to the second monitor, such that the peripheral edges of the third display are offset from the peripheral edges of the two displays.

With reference to FIGS. 1-8A, the following description is an example assembly and operation process for the portable display system 10. It should be understood that the described process is for illustration purposes only and the steps are not intended to be required or exhaustive, and the particular order described is not intended to be limiting.

In an example operation, the portable display system 10 may be transported to a desired location using any or all of the handles 50, 55, 60, 65, 70. Once at the desired location, the portable display system 10 is set on a surface and the feet 85, 86, 87, 88 are extended to a desired length 91 and locked using the push-pin button 90. The latches 45 are disengaged and the lid 40 is removed and set aside, exposing the first and second displays 105, 145 in their stow positions 295, 300. Padding and other protective material may be removed from the housing 15 and set aside, or in embodiments where some or all of the padding is anchored in place and not disturbed during display extension or use, the padding may be left in place.

Thereafter, the pin clips 175 are disengaged from the housing mounts 200 and the second display 145 is removed from the housing 15. The connecting mounts 150 of the second display 145 are inserted into the receiving mounts 130 of the first display 105. Once the receiving and connecting mounts 130, 150 are coupled, the side openings 195, 196 of the tubular bodies 131, 151 are brought into alignment. The elongated pin 190 of each of the pin clips 175 is inserted into the side openings 195, 196 of the receiving and connecting mounts 130, 150, respectively, to stabilize the multiple-display unit 100. Additional displays may be added to the multiple-display unit 100 and configured as desired.

Once all the displays have been secured, wiring (not shown) from the first and second displays 105, 145 is connected to an internal power receptacle 210. The first and second displays 105, 145 may be individually connected to power receptacle 210 or electrically coupled to each other and a single power cable can be connected to power receptacle 210. A power cord (not shown) is then connected to the electrical panel 215 and into an external power source (not shown) to provide power to the multiple-display unit 100 and the first and second displays 105, 145. Thereafter, the multiple-display unit 100 is raised to a desired viewing position 290 using a remote control to operate the first and second movable supporting members 110, 115. Once the multiple-display unit 100 reaches the viewing position 290, the first and second displays 105, 145 are configured to display maps, images, plans, communications, or other data as desired. Each of the first and second displays 105, 145 may be controlled through wired or wireless connection, such as via a laptop computer, mobile phone application, or other computing device.

Once the multiple-display unit 100 is no longer needed, the wiring and power cords are all disconnected and the first and second movable supporting members 110, 115 are lowered to return the first display 105 to its stow position 300. The pin clips 175 are removed and the connecting mounts 150 of the second display 145 are disengaged from the receiving mounts 130 of the first display 105. Next, the connecting mounts 150 of the second display 145 are inserted into the housing mounts 200 and the pin clips 175 are reinserted through the side openings 196, 203 of the connecting and housing mounts 150, 200, respectively, to secure the second display 145 in the housing 15. Thereafter, the first and second displays 105, 145 are surrounded by the protective material and the lid 40 is secured onto the housing 15 using the latches 45. Finally, the feet 85, 86, 87, 88 are unlocked and retracted until push-pin button 90 engages opening 95.

FIG. 10 illustrates another embodiment of the portable display system 10 with a plurality of side-by-side and vertically-stacked displays in the same plane. The portable display system 10 may include first and second movable supporting members 220, 225 and a pair of base displays 230, 235 each coupled to one of the first and second movable supporting members 220, 225 in a fashion similar as described previously. Additional displays 240 as desired may be coupled to base displays 230, 235 using similar attachment mechanisms as described with respect to the receiving and connecting mounts 130, 150 (see FIGS. 5-8A). To increase stability of the multiple-display unit 100, the base displays 230, 235 and additional displays 240 may include both vertical and horizontal connecting and receiving mounts such that the base displays 230, 235 and additional displays 240 can be horizontally and vertically coupled to adjacent displays. The feet 85, 86, 87, 88 may also be extended to have greater lengths 91, such as more than ⅛ the length of the right side wall 20 to help stabilize the multiple-display unit 100. In some embodiments, the feet 85, 86, 87, 88 may extend to a length 91 of three or more inches beyond the exterior surfaces of the front and back side walls 25, 30.

In other embodiments, additional movable supporting members may be incorporated to help stabilize the multiple-display unit 100. For example, a third and fourth movable supporting member (not shown) may be incorporated and laterally spaced apart from the first and second movable supporting members, respectively, and parallel to the front and back side walls 25, 30, to provide additional support for each of the base displays 230, 235. In yet other embodiments, base displays 230, 235 and additional displays 240 may be housed in the housing 15 in a similar fashion as previously described with relation to the second display 145 and the housing mounts 200 (FIGS. 3 and 4).

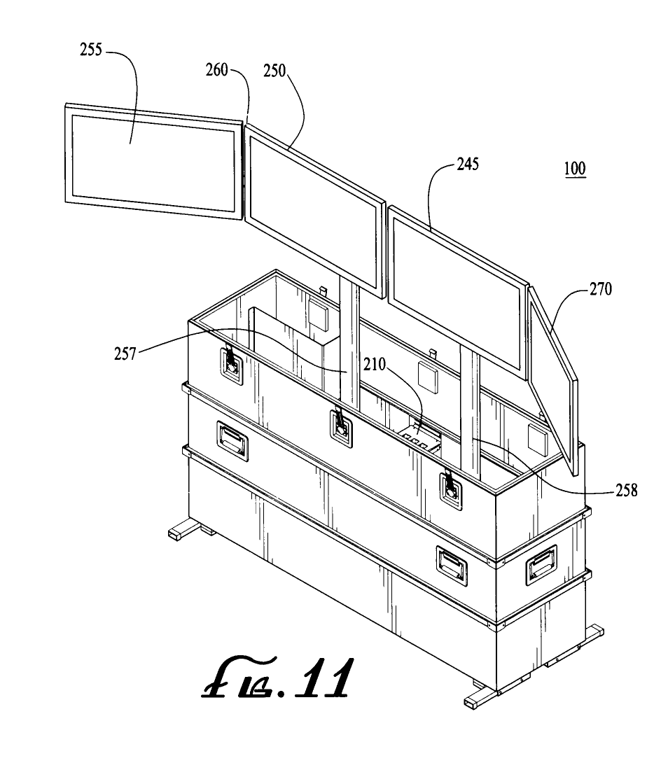

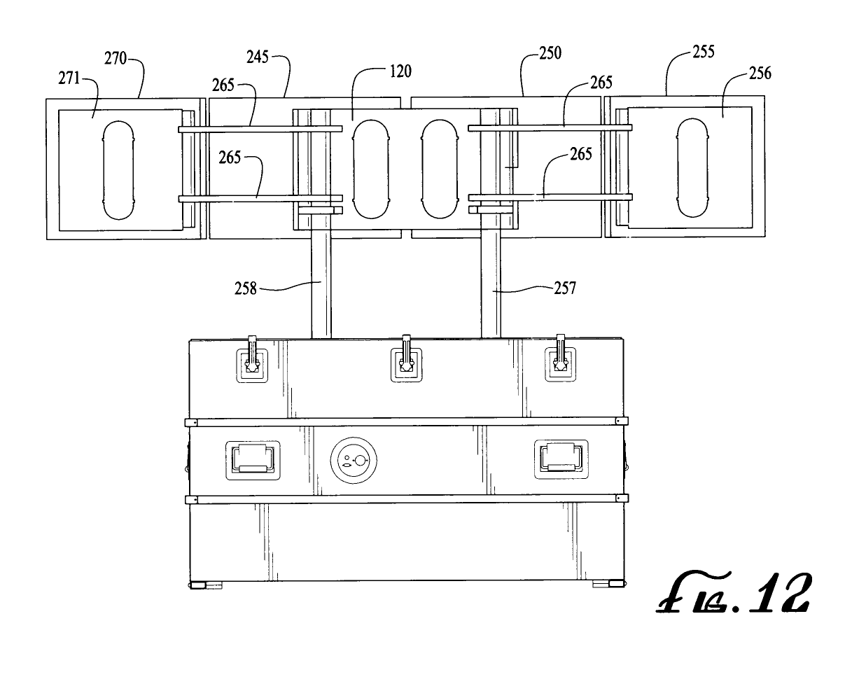

FIGS. 11 and 12 illustrate other embodiments of a multiple-display unit 100 with a pair of base displays 245, 250 attached to a pair of movable supporting members 257, 258 in a similar fashion as described previously. The multiple-display unit 100 further includes a first rotatable display 255 pivotably attached to a peripheral edge 260 of base display 250 using at least one pivoting connector 265, such as a hinged clamp system, a hinged connector, a ball and socket linkage, or other pivoting linkage. The pivoting connector 265 may be mounted on one end to the support plate 120, where the support plate 120 spans across the two base displays 245, 250. The other end of the pivoting connector 265 may be attached to a support plate 256 attached to the first rotatable display 255. A second rotatable display 270 may be attached in a similar fashion to base display 245 as described with respect to the first rotatable display 255, including the pivoting connector 265 attached to the support plate 271 on one end and to the support plate 120 on the other end. Alternatively, each of the base displays 245, 250 may have a support plate and the pivoting connector 265 may be attached to the support plate of each of the base displays 245, 250 and on the other end to the rotatable displays 255, 270, respectively. The pivoting connector 265 allows the first and second rotatable displays 255, 270 to rotate in relation to base displays 245, 250, respectively.

The first and second rotatable displays 255, 270 may rotate along a substantially unencumbered range of motion in both an inward and outward direction. For example, the first and second rotatable displays 255, 270 may rotate inward to create a panoramic display for a user or users standing substantially in the center of the multiple-display unit 100. Additionally, the rotatable displays 255, 270 may rotate outward to allow other users standing off to a left or right side of the multiple-display unit 100 to view images or data being displayed on the first and second rotatable displays 255, 270. The pivoting connector 265 may include openings aligned at different preset angles to allow the rotating displays 255, 270 to be locked in various angular positions as desired. The openings may be set at different heights and positions along the pivoting connector 265 so as to not compromise the structural integrity of the pivoting connector 265.

In a preferred embodiment, the multiple-display system 100 may be stored without requiring removal of any of the displays 245, 250, 255, 270. In one example embodiment, the rotatable displays 255, 270 may fully rotate inwardly or outwardly toward base displays 245, 250, respectively, such that each rotatable display 255, 270 is substantially parallel to the base displays 245, 250, respectively. Padding or protective material as necessary may be inserted between the base displays 245, 250 and rotatable displays 255, 270 to help protect and stabilize the displays. Once the displays are secured, the movable supporting members 257, 258 may be lowered to store the displays 245, 250, 255, 270 within the housing 15.

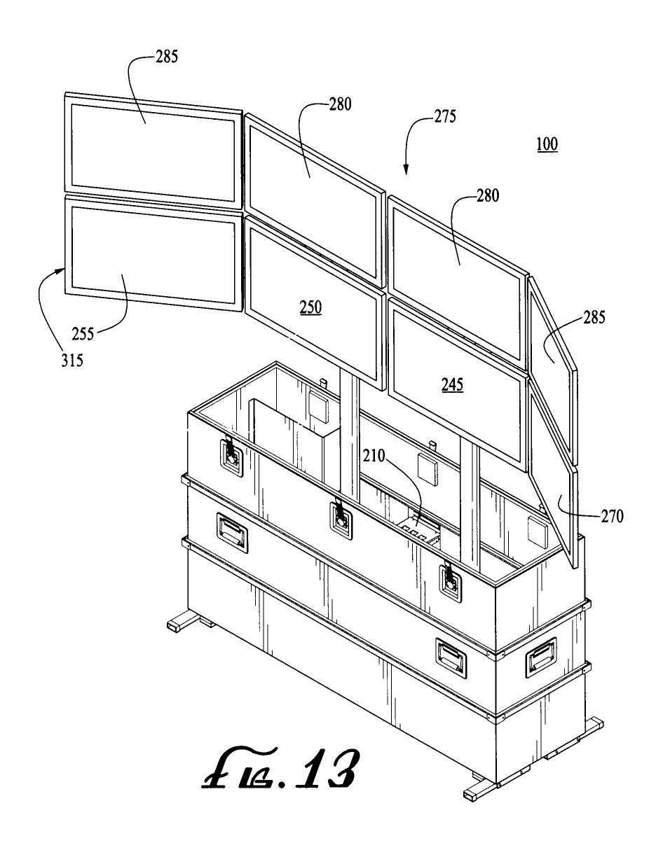

FIG. 13 illustrates yet another embodiment of a multiple-display unit 100 similar to FIG. 11 or 12 but with an additional array of displays 275 including a second upper pair of base displays 280 and a pair of upper rotatable displays 285. The second pair of upper base displays 280 and upper rotatable displays 285 may be coupled to the base displays 245, 250 and rotatable displays 255, 270, respectively, in a similar fashion as previously described with respect to receiving and connecting mounts 130, 150 or may be coupled using other mounting mechanisms. Similarly, the upper rotatable displays 285 may be coupled to the base displays 280 in a similar fashion as previously described with respect to the first and second rotatable displays 255, 270. In some embodiments, upper rotatable displays 285 may not be coupled directly to rotatable displays 255, 270 so as to allow for independent rotation of the rotatable displays 255, 270, 285 to provide alternate viewing angles to a group of users.

In another embodiment, the array of displays 275 may be rotatably coupled to base displays 245, 250 and first and second rotatable displays 255, 270 using the pivoting connector 265 such that the array of displays 275 can rotate in a forward direction toward a user standing in front of the multiple-display unit 100 or a backward direction away from the user. The backward rotation may provide additional viewing angles for other users, such as those that may be positioned at a distance and a higher elevation.

It should be understood that embodiments other than those described and illustrated in the figures may include a different number and arrangement of displays, including multiple rotatable displays. For example, an additional rotatable display (not shown) may be added to a peripheral edge 315 of the first rotatable display 255 or an additional stationary display (not shown) may be added between the base display 250 and the first rotatable display 255 to create a longer horizontal array of displays.

It should also be understood that any concept, embodiment, or example disclosed in any sentence, paragraph, or section disclosed herein can be combined with any other concept, embodiment, or example disclosed in any other sentence, paragraph or section, unless such concepts are mutually exclusive.

It will be obvious to those having skill in the art that many changes may be made to the details of the above-described embodiments without departing from the underlying principles of the embodiments described herein. The scope of the present invention should, therefore, be determined only by the following claims.

1. A portable system for display storage and use, the system comprising:
a housing having a bottom wall and a plurality of side walls defining a cavity, the bottom wall having an interior surface facing the cavity;
a first display housed in the cavity;
a second display removably coupled to the first display to form a multiple-display unit; and
a first movable supporting member having a first end coupled to the first display and an opposing second end coupled to the housing, wherein the first movable supporting member is operable to move the multiple-display unit between a first position where the first display is housed in the cavity and a second position where the multiple-display unit is extended to a height above the housing.

2. The system of claim 1, further comprising:
a first receiving mount attached to the first display; and
a first connecting mount attached to the second display, wherein the first receiving mount is sized and arranged to fit the first connecting mount for removably coupling the first and second displays.

3. The system of claim 2, wherein the first receiving mount and first connecting mount each include an elongate tubular body having an opening on one end, and wherein the elongate tubular body of the first receiving mount is sized to slidably receive the elongate tubular body of the first connecting mount.

4. The system of claim 2, wherein the first receiving mount and the first connecting mount are oriented along a vertical axis such that the second display is removably coupled to the first display in a vertical alignment where the first and second displays are in one plane.

5. The system of claim 2, wherein the first receiving mount and the first connecting mount are oriented along a horizontal axis such that the second display is removably coupled to the first display in a horizontal alignment where the first and second displays are in one plane.

6. The system of claim 2, further comprising:
a second receiving mount attached to the first display and laterally spaced apart from the first receiving mount; and
a second connecting mount attached to the second display and laterally spaced apart in the same plane from the first connecting mount, wherein the first and second connecting mounts are sized and arranged to slidably fit the first and second receiving mounts.

7. The system of claim 1, further comprising:
a first and second connecting mount coupled to the second display; and
a first and second storing mount coupled to the interior surface of the bottom wall of the housing, the first and second storing mounts sized to receive the first and second connecting mounts.

8. The system of claim 7, further comprising:
a first and second receiving mount attached to the first display, wherein the first and second receiving mounts are sized to receive the first and second connecting mounts coupled to the second display, and wherein the first and second receiving mounts are sized substantially identically to the first and second storing mounts, such that the second display can be removably coupled to the first and second receiving mounts and the first and second storing mounts.

9. The system of claim 1, further comprising:
a second movable supporting member having a first end coupled to the first display and a second end coupled to the housing, wherein the second movable supporting member is laterally spaced apart in one plane from the first movable supporting member, and wherein the second movable supporting member is synchronized with the first movable supporting member and operable to move the multiple-display unit between a first position where the first display is housed in the cavity and a second position where the multiple-display unit is extended to a height above the housing.

10. A portable system for display storage and use, the system comprising:
a housing having a bottom wall and a plurality of side walls defining a cavity;
a first display directly or indirectly rotatably coupled to a second display to form a multiple-display unit; and
a first movable supporting member having a first end coupled to the first display and an opposing second end coupled to the housing, wherein the first movable supporting member is operable to move the multiple-display unit between a first position where the multiple-display unit is housed in the cavity and a second position where the multiple-display unit is extended to a height above the housing.

11. The system of claim 10, wherein the second display is rotatably coupled to the first display in a substantially horizontal alignment where the first and second displays are in one plane, and wherein the second display is rotatable relative to the first display.

12. The system of claim 10, wherein the second display is rotatably coupled to the first display in a substantially vertical alignment where the first and second displays are in one plane, and wherein the second display is rotatable relative to the first display.

13. The system of claim 10, further comprising:
a third display directly or indirectly rotatably coupled to a fourth display, wherein the fourth display is rotatable relative to the third display, and wherein the third display is directly or indirectly coupled to the first display to form a multiple-display unit; and
a second movable supporting member having a first end coupled to the third display and a second end coupled to the housing, wherein the second movable supporting member is laterally spaced apart from the first movable supporting member, and wherein the second movable supporting member is operable to move the multiple-display unit between a first position where the multiple-display unit is housed in the cavity and a second position where the multiple-display unit is extended to a height above the housing.

14. A portable case for monitor storage, the case comprising:
a housing having a bottom wall and a plurality of side walls including opposing first and second side walls, wherein the bottom wall and the plurality of side walls define a cavity;
a first and second handle, wherein the first handle is coupled to an exterior-facing surface of the first side wall and the second handle is coupled to an exterior-facing surface of the second side wall;
at least one latch coupled to an exterior-facing surface of one of the plurality of side walls;
an enclosure sized to fit the housing for covering the cavity, wherein the enclosure is secured to the housing by the at least one latch; and
a first balancing foot coupled to the housing along an exterior-facing surface of the bottom wall, wherein at least a portion of the first balancing foot is extendable for helping balance the portable case while on a surface.

15. The case of claim 14, further comprising:
a locking mechanism positioned along the first balancing foot and operable to lock the first balancing foot in an extended position.

16. The case of claim 14, further comprising:
a second balancing foot coupled to the housing and laterally spaced apart from the first balancing foot;
a third balancing foot coupled to the housing and positioned along the exterior-facing surface of the bottom wall opposite the first balancing toot;
a fourth balancing foot coupled to the housing and laterally spaced apart from the third balancing foot; and
a locking mechanism positioned along each of the second, third, and fourth balancing foot;
wherein each of the second, third, and fourth balancing foot is individually extendable for helping balance the portable case while on a surface, and wherein the locking mechanism is operable to lock each of the second, third, and fourth balancing foot in an extended position.

17. A portable system for display storage and use, the system comprising:
a housing having a bottom wall and a plurality of side walls defining a cavity, the bottom wall having an interior bottom surface facing the cavity, and the plurality of side walls each having an interior side wall surface facing the cavity;
a first display housed in the cavity, the first display having a receiving mount adapted to couple with a connecting mount attached to a second display;
a first movable supporting member having a first end coupled to the first display and an opposing second end directly or indirectly coupled to the housing, wherein the first movable supporting member is operable to move the multiple-display unit between a first position where the first display is housed in the cavity and a second position where the first display is extended to a height above the housing; and
a housing mount directly or indirectly coupled to the interior bottom surface or at least one of the interior side wall surfaces, the housing mount being adapted to couple with the connecting mount attached to the second display.

18. The system of claim 17, in which the bottom wall has an exterior bottom surface and each of the side walls having an exterior side wall surface, the system further comprising:
a balancing foot coupled to the exterior bottom wall surface or at least one of the exterior side wall surfaces, wherein at least a portion of the balancing foot is extendable in an outward direction in relation to at least one of the exterior side wall surfaces.

19. A method comprising:
opening a portable container housing a first and second display, where the first display is coupled to a movable supporting member;
removing the second display from the portable container;
coupling the second display to the first display; and
elevating the coupled first and second displays using the movable supporting member.

20. The method of claim 19, wherein coupling the second display to the first display comprises sliding a connecting mount located on the second display into a corresponding receiving mount located on the first display.

21. A method comprising:
coupling a movable supporting member to an interior housing of a portable container;
coupling a first display to the movable supporting member;
arranging storing mounts on the interior housing of the portable container; and
coupling a second display with the storing mounts, wherein the first display is spaced apart from the second display.
